(19) United States
(12) Patent Application Publication
(10) Pub. No.: US 2022/0341765 A1
(43) Pub. Date: Oct. 27, 2022

(54) PEOPLE FLOW MEASURING DEVICE, PEOPLE FLOW MEASURING METHOD, PEOPLE FLOW SIMULATION SYSTEM, PEOPLE FLOW SIMULATION METHOD, AND PEOPLE FLOW SIMULATION PROGRAM

(71) Applicant: NIPPON TELEGRAPH AND TELEPHONE CORPORATION, Tokyo (JP)

(72) Inventors: Yusuke TANAKA, Tokyo (JP); Shinya OI, Tokyo (JP); Koshin TO, Tokyo (JP); Masaru MIYAMOTO, Tokyo (JP)

(73) Assignee: NIPPON TELEGRAPH AND TELEPHONE CORPORATION, Tokyo (JP)

(21) Appl. No.: 17/762,720

(22) PCT Filed: Sep. 25, 2019
(86) PCT No.: PCT/JP2019/037542

§ 371 Date: Mar. 22, 2022

(51) Int. Cl. G01D 21/00; G06F 30/20

(52) U.S. Cl. CPC G01D 21/00; G06F 30/20

(57) ABSTRACT

The present invention can perform a human flow simulation in real time. An input unit (102) receives an input of passage information indicating passage through a point, a measurement unit (103) measures the number of passing people through the point by adding the received passage information, and a transmission unit (104) transmits the number of passing people measured by the measurement unit (103) at a predetermined time interval to a server that generates a parameter of a human flow simulation.

### TECHNICAL FIELD

The present disclosure relates to a human flow measurement apparatus, a human flow measurement method, a human flow measurement program, a human flow simulation system, a human flow simulation method, and a human flow simulation program.

### BACKGROUND ART

In the related art, the number of passing people through a point is measured by a person performing a measurement by using a counter (for example, NPL 1). In a human flow simulation, a parameter used for a simulation is generated by using a measurement result of a measurement by the method.

### CITATION LIST

### Non Patent Literature

NPL 1: Victoria walks, “Measuring Walking-A Guide for Councils”, [online], [Search on Aug. 27, 2019], Internet <URL: http://www.victoriawalks.org.au/Assets/Files/FINAL_Guide_to_measuring_walking_WEBv1.0%20Dated.pdf>.

### SUMMARY OF THE INVENTION

### Technical Problem

However, when a person performs a measurement, measurement data is collected and reflected in a simulator after a measurement by a counter, and thus there is a problem in that it takes time to reflect a collected result in the simulator, and a human flow simulation cannot be performed in real time.

The disclosed technique has been made in view of the points described above, and an object thereof is to provide a human flow measurement apparatus, a human flow measurement method, a human flow measurement program, a human flow simulation system, a human flow simulation method, and a human flow simulation program capable of performing a human flow simulation in real time.

### Means for Solving the Problem

A first aspect of the present disclosure is a human flow measurement apparatus including an input unit configured to receive an input of passage information indicating passage through a point, a measurement unit configured to measure the number of passing people through the point by adding the passage information received at the input unit, and a transmission unit configured to transmit the number of passing people measured at the measurement unit at a predetermined time interval to a server that generates a parameter of a human flow simulation.

A second aspect of the present disclosure is a human flow measurement method including receiving, at an input unit, an input of passage information indicating passage through a point, measuring, at a measurement unit, the number of passing people through the point by adding the passage information received at the input unit, and transmitting, at a transmission unit, the number of passing people measured at the measurement unit at a predetermined time interval to a server that generates a parameter of a human flow simulation.

A third aspect of the present disclosure is a human flow measurement program, and the human flow measurement program causes a computer to execute processing including receiving, at an input unit, an input of passage information indicating passage through a point, measuring, at a measurement unit, the number of passing people through the point by adding the passage information received at the input unit, and transmitting, at a transmission unit, the number of passing people measured at the measurement unit at a predetermined time interval to a server that generates a parameter of a human flow simulation.

A fourth aspect of the present disclosure is a human flow simulation method including a human flow measurement apparatus including an input unit, a measurement unit, and a transmission unit, and a server including a reception unit and a parameter generation unit, receiving, at the input unit, an input of passage information indicating passage through a point, measuring, at the measurement unit, the number of passing people through the point by adding the passage information received at the input unit, transmitting, at the transmission unit, the number of passing people measured at the measurement unit at a predetermined time interval to the server, receiving, at the reception unit, the number of passing people, and generating, at the parameter generation unit, a parameter for executing a human flow simulation, based on the received number of passing people and predetermined simulation information.

A fifth aspect of the present disclosure is a human flow simulation program, and the human flow simulation program causes a computer to execute processing including receiving, at an input unit, an input of passage information indicating passage through a point, measuring, at a measurement unit, the number of passing people through the point by adding the passage information received at the input unit, and generating, at a parameter generation unit, a parameter for executing a human flow simulation, based on the number of passing people measured at the measurement unit at a predetermined time interval, and predetermined simulation information.

### Effects of the Invention

According to the disclosed technique, a human flow simulation can be performed in real time.

### BRIEF DESCRIPTION OF DRAWINGS

FIG. 1 is a diagram illustrating a configuration of a human flow simulation system according to a first embodiment.

FIG. 2 is a block diagram illustrating a hardware configuration of a human flow measurement apparatus according to the first embodiment.

FIG. 3 is a block diagram illustrating an example of a functional configuration of the human flow measurement apparatus according to the first embodiment.

FIG. 4 is an example of a screen displayed by a display unit.

FIG. 5 is a diagram illustrating an example in which a point, a time, and the number of passing people are counted.

FIG. 6 is a block diagram illustrating a hardware configuration of a server according to the first embodiment.

FIG. 7 is a block diagram illustrating an example of a functional configuration of the server according to the first embodiment.

FIG. 8 is a diagram illustrating an example of a result of a human flow simulation by the human flow simulation system.

FIG. 9 is a flowchart illustrating a sequence of a human flow measurement processing routine by the human flow measurement apparatus according to the first embodiment.

FIG. 10 is a flowchart illustrating a sequence of a human flow simulation processing routine by the server according to the first embodiment.

FIG. 11 is a diagram illustrating an outline of a human flow simulation system according to a second embodiment.

FIG. 12 is a diagram illustrating a configuration of the human flow simulation system according to the second embodiment.

FIG. 13 is a block diagram illustrating a hardware configuration of a sensor apparatus according to the second embodiment.

FIG. 14 is a block diagram illustrating an example of a functional configuration of the sensor apparatus according to the second embodiment.

FIG. 15 is a block diagram illustrating an example of a functional configuration of a server according to the second embodiment.

FIG. 16 is a flowchart illustrating a sequence of a sensor measurement processing routine by the sensor apparatus according to the second embodiment.

FIG. 17 is a flowchart illustrating a sequence of a human flow simulation processing routine by the server according to the second embodiment.

### DESCRIPTION OF EMBODIMENTS

Configuration of Human Flow Simulation System According to First Embodiment Hereinafter, an example of a first embodiment of the disclosed technique will be described with reference to the drawings. In the drawings, the same reference numerals are given to the same or equivalent constituent elements and parts. The dimensional ratios in the drawings are exaggerated for convenience of explanation and may differ from the actual ratios.

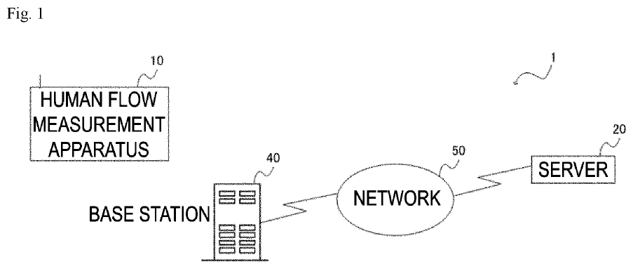

FIG. 1 is a diagram illustrating a configuration of a human flow simulation system 1 according to the present embodiment. As illustrated in FIG. 1, the human flow simulation system 1 includes a human flow measurement apparatus 10, a server 20, a base station 40, and a network 50. The human flow measurement apparatus 10 and the server 20 communicate with each other via the base station 40 and the network 50. The base station 40 is a radio base station, and the network 50 is a wide area network such as the Internet.

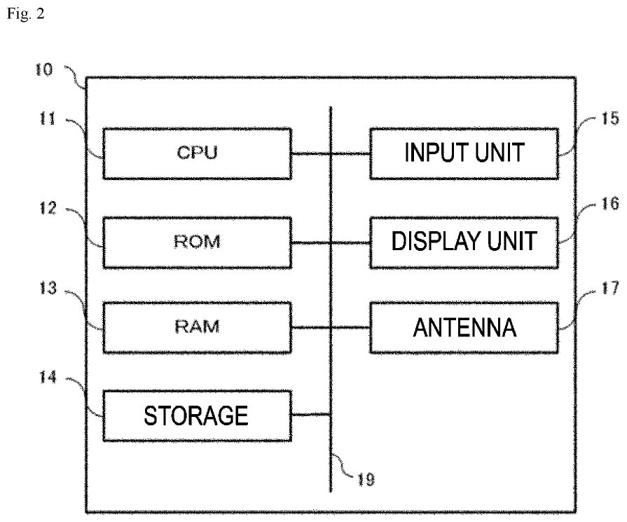

FIG. 2 is a block diagram illustrating a hardware configuration of the human flow measurement apparatus 10 according to the present embodiment. As illustrated in FIG. 2, the human flow measurement apparatus 10 includes a central processing unit (CPU) 11, a read only memory (ROM) 12, a random access memory (RAM) 13, a storage 14, an input unit 15, a display unit 16, and an antenna 17. The components are communicably interconnected through a bus 19.

The CPU 11 is a central processing unit that executes various programs and controls each unit. In other words, the CPU 11 reads a program from the ROM 12 or the storage 14 and executes the program using the RAM 13 as a work area. The CPU 11 performs control of each of the components described above and various arithmetic processing operations in accordance with a program stored in the ROM 12 or the storage 14. In the present embodiment, a human flow measurement program is stored in the ROM 12 or the storage 14.

The ROM 12 stores various programs and various kinds of data. The RAM 13 is a work area that temporarily stores a program or data. The storage 14 is constituted by a storage device such as a hard disk drive (HDD) or a solid state drive (SSD) and stores various programs including an operating system and various kinds of data.

The input unit 15 includes a pointing device such as a mouse and a keyboard and is used for performing various inputs.

The display unit 16 is, for example, a liquid crystal display and displays various kinds of information. The display unit 16 may adopt a touch panel method and function as an input unit 15.

The antenna 17 is an antenna for performing wireless communication with other devices and uses standards such as, for example, Wi-Fi (registered trademark) and LTE.

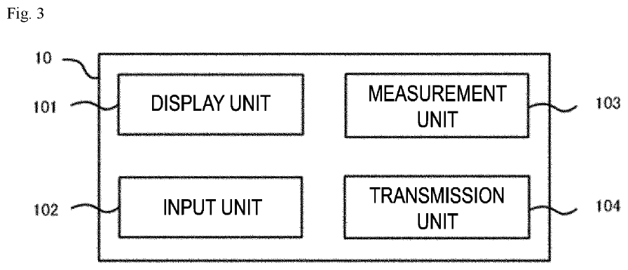

Next, a functional configuration of the human flow measurement apparatus 10 will be described. The single human flow measurement apparatus 10 can simultaneously perform a measurement at a plurality of points by one measurer. Note that the points are set in advance. FIG. 3 is a block diagram illustrating an example of a functional configuration of the human flow measurement apparatus 10.

As illustrated in FIG. 3, the human flow measurement apparatus 10 includes, as a functional configuration, a display unit 101, an input unit 102, a measurement unit 103, and a transmission unit 104. Each of the functional configurations is implemented by the CPU 11 reading the human flow measurement program stored in the ROM 12 or the storage 14, and loading the human flow measurement program in the RAM 13 to execute the program.

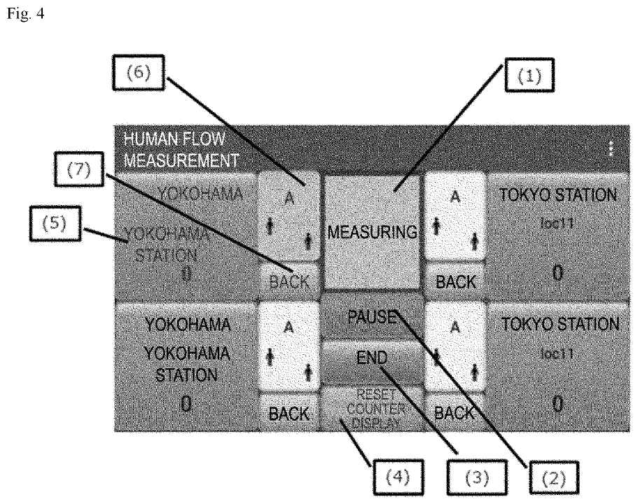

The display unit 101 displays a screen for receiving passage information about each of a plurality of points indicating passage through the point. Specifically, information required for a measurement by the human flow measurement apparatus 10 is displayed on the screen. FIG. 4 is an example of a screen displayed by the display unit 101. In the present embodiment, the screen is described as being a graphical user interface (GUI). A function of the screen based on the GUI constructed by a script language and the like is described as being processed by the display unit 101.

In the screen in FIG. 4, (1) is a “mode display”, (2) is a “start (resume)/pause” button, (3) is an “end” button, (4) is a “reset” button, (5) is a “count-up” button, (6) is a “congestion level” button, and (7) is a “back” button. The “mode display” displays a state of a measurement. A state of a measurement includes pre-measurement, measuring, pausing, and the like. The “start (resume)/pause” button is a display for starting a measurement when a state of the measurement is pre-measurement, is a display for pausing a measurement when a state of the measurement is measuring, and is a display for resuming a measurement when a state of the measurement is pausing. A measurement starts, pauses, or resumes by the “start (resume)/pause” button being tapped. The “end” button is a button for ending a measurement. A measurement ends by the “end” button being tapped. The “reset” button is a button for resetting a counter display and a congestion level. By the “reset” button being tapped, a counter display at all points is reset to zero and a congestion level is also reset. Note that a counter display and a congestion level for each point may be configured to be individually reset. The “count-up” button displays a name of a point and a counter being a current number of measurements. Further, when the “count-up” button is tapped, a counter is incremented by one for a corresponding point. The “congestion level” button displays a congestion level indicating a degree of congestion for a corresponding point. The congestion level is set to ranks from A to F, for example. When the “congestion level” button is tapped, a button for selecting a congestion level is displayed on the “count-up” button. By a congestion level displayed on the button for selecting a congestion level being tapped, the congestion level is set. The “back” button is a button for reducing a counter. When the “back” button is tapped, a counter is decremented by one for a corresponding point.

Further, when the “count-up” button is tapped, the display unit 101 passes passage information about a corresponding point to the input unit 102. Further, when the “back” button is tapped, the display unit 101 passes, to the input unit 102, cancellation information for canceling passage through a corresponding point.

The input unit 102 receives, from the display unit 101, an input of the passage information and the cancellation information about each of the plurality of points. Specifically, the input unit 102 receives the passage information from the display unit 101 by the “count-up” button being tapped. The input unit 102 receives the cancellation information from the display unit 101 by the “back” button being tapped. Then, the input unit 102 passes the passage information and the cancellation information to the measurement unit 103 every time the passage information and the cancellation information are received. The input unit 102 can also receive information about a point such as a name of a point. In this case, the input unit 102 passes the received information about the point to the display unit 101. In other words, in this case, the display unit 101 performs setting of the screen, such as displaying the name of the point on the “count-up” button, based on the information about the point.

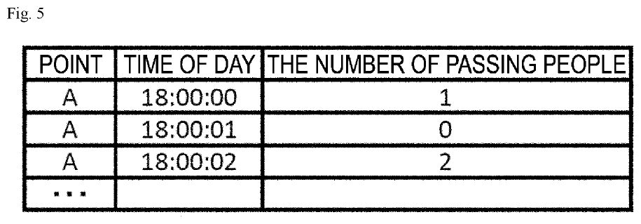

The measurement unit 103 measures the number of passing people through the point by adding the passage information about each of the plurality of points being received by the input unit 102. Specifically, when the measurement unit 103 receives the passage information from the input unit 102, the measurement unit 103 first associates a point corresponding to the passage information with a time at which the passage information is received. Next, the measurement unit 103 adds one to the number of passing people through the point associated with the passage information. Further, when the measurement unit 103 receives the cancellation information, the measurement unit 103 subtracts one from the number of passing people through a point corresponding to the cancellation information. The measurement unit 103 deletes a time of a point in time when the number of passing people through the point corresponding to the cancellation information is added, which is the time closest to a time at which the cancellation information is received. By repeating the processing described above, the measurement unit 103 counts the number of passing people. For example, as illustrated in FIG. 5, a point, a time, and the number of passing people are counted. FIG. 5 illustrates an example in which passage information is collected and added every second.

Then, the measurement unit 103 passes, to the transmission unit 104, the number of passing people through each of a plurality of points at a predetermined time interval after a lapse of the predetermined time interval. The predetermined time interval may be a time interval suitable for performing a real-time simulation, e.g., one minute. For example, if the time interval is 17:59 to 18:00, the measurement unit 103 passes, to the transmission unit 104, the number of passing people through each of a plurality of points at 18:00 after a lapse of one minute.

The transmission unit 104 transmits the number of passing people measured by the measurement unit 103 at the predetermined time interval to the server 20 that generates a parameter of a human flow simulation. Specifically, when the transmission unit 104 receives the number of passing people through each of a plurality of points from the measurement unit 103, the transmission unit 104 transmits, to the server 20, the number of passing people through each of the plurality of points and the time interval at an earliest possible time for transmission.

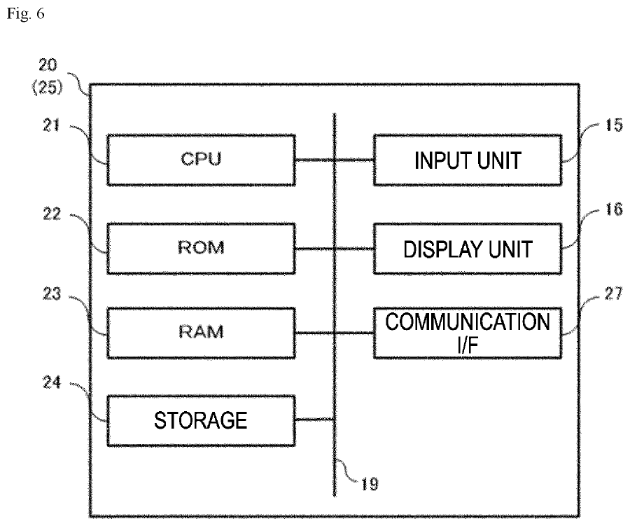

Next, a configuration of the server 20 will be described. The same components as those of the human flow measurement apparatus 10 described above are denoted by the same reference signs and detailed description thereof will be omitted. FIG. 6 is a block diagram illustrating a hardware configuration of the server 20 according to the present embodiment. As illustrated in FIG. 6, the server 20 includes a CPU 21, a ROM 22, a RAM 23, a storage 24, an input unit 15, a display unit 16, and a communication interface (I/F) 27. The components are communicably interconnected through a bus 19.

The CPU 21 is a central processing unit that executes various programs and controls each unit. In other words, the CPU 21 reads a program from the ROM 22 or the storage 24 and executes the program using the RAM 23 as a work area. The CPU 21 performs control of each of the components described above and various arithmetic processing operations in accordance with a program stored in the ROM 22 or the storage 24. In the present embodiment, a human flow simulation program for executing human flow simulation processing is stored in the ROM 22 or the storage 24.

The ROM 22 stores various programs and various kinds of data. The RAM 23 is a work area that temporarily stores a program or data. The storage 24 is constituted by an HDD or a SSD, and stores various programs including an operating system and various kinds of data.

The communication interface 27 is an interface for communicating with other devices and uses standards such as, for example, Ethernet (registered trademark), FDDI, and Wi-Fi (registered trademark).

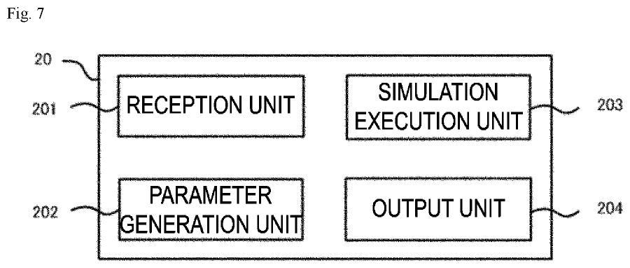

Next, a functional configuration of the server 20 will be described. FIG. 7 is a block diagram illustrating an example of the functional configuration of the server 20. As illustrated in FIG. 7, the server 20 includes, as a functional configuration, a reception unit 201, a parameter generation unit 202, a simulation execution unit 203, and an output unit 204. Each of the functional configurations is implemented by the CPU 21 reading the human flow simulation program stored in the ROM 22 or the storage 24, and loading the human flow simulation program into the RAM 23 to execute the program.

The reception unit 201 receives, from the human flow measurement apparatus 10, the number of passing people through each of the plurality of points. Then, the reception unit 201 passes, to the parameter generation unit 202, the received number of passing people through each of the plurality of points.

The parameter generation unit 202 generates a parameter for executing a human flow simulation, based on the received number of passing people through each of the plurality of points and predetermined simulation information. The simulation information is setting information for executing a preset human flow simulation. The parameter generation unit 202 generates a parameter, based on the number of passing people through each of the plurality of points and the predetermined simulation information every time the number of passing people through each of the plurality of points is received. Then, the parameter generation unit 202 passes the generated parameter to the simulation execution unit.

The simulation execution unit 203 executes a human flow simulation, based on the parameter generated by the parameter generation unit 202 and the predetermined simulation information. Specifically, the simulation execution unit 203 executes a human flow simulation in which the number of passing people through each of the plurality of points is estimated at a next time interval of a time interval of the number of passing people being used last by the parameter generation unit 202. Then, the simulation execution unit 203 passes a result of the human flow simulation to the output unit 204.

The output unit 204 outputs the simulation result executed by the simulation execution unit 203.

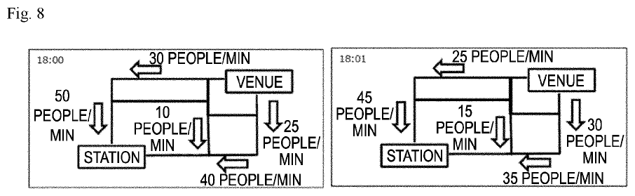

FIG. 8 illustrates an example of a result of a human flow simulation by the human flow simulation system 1. When a time interval is one minute, the human flow simulation can be executed at 18:00 and 18:01, as illustrated in FIG. 8. In other words, a situation can be reflected in real time according to a time interval. By bringing the human flow measurement apparatus 10 and the server 20 in cooperation with each other online and reflecting a situation in a parameter of the simulation execution unit 203 in real time, a simulation based on the real-time situation can be achieved.

### Effect of Human Flow Simulation System According to First Embodiment

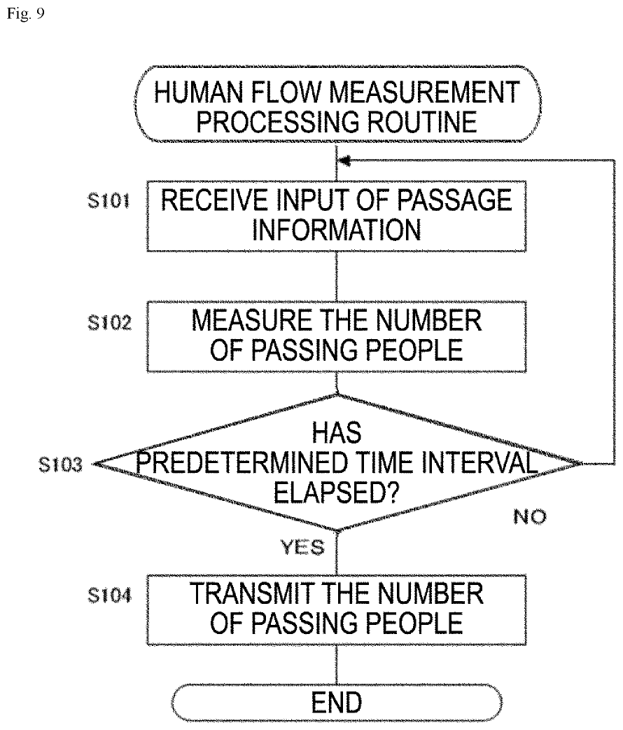

Next, effects of the human flow measurement apparatus 10 will be described. FIG. 9 is a flowchart illustrating a sequence of a human flow measurement processing routine by the human flow measurement apparatus 10. The CPU 11 reads the human flow measurement program from the ROM 12 or the storage 14, loads the human flow measurement program into the RAM 13, and executes the human flow measurement program, whereby the processing by the human flow measurement apparatus 10 is performed. By the “start (resume)/pause” button on the screen displayed by the display unit 101 being tapped in a state where a human flow measurement has not been started, the human flow measurement processing routine starts.

In step S101, the CPU 11 serves as the input unit 102, and receives an input of passage information about each of a plurality of points.

In step S102, the CPU 11 serves as the measurement unit 103, and measures the number of passing people through the point by adding the passage information about each of the plurality of points being received in step S102 described above.

In step S103, the CPU 11 serves as the measurement unit 103, and determines whether a predetermined time interval has elapsed.

In accordance of a determination that the predetermined time interval has not elapsed (NO in step S103 described above), the processing returns to step S101.

On the other hand, in accordance of a determination that the predetermined time interval has elapsed (YES in step S103 described above), in step S104, the CPU 11 serves as the transmission unit 104, and transmits, to the server 20 that generates a parameter of a human flow simulation, the number of passing people measured by the CPU 11 as the measurement unit 103 at the predetermined time interval.

The human flow measurement apparatus 10 repeats the processing until the “end” button is tapped. In other words, the human flow measurement apparatus 10 repeats the processing by the “end” button being tapped.

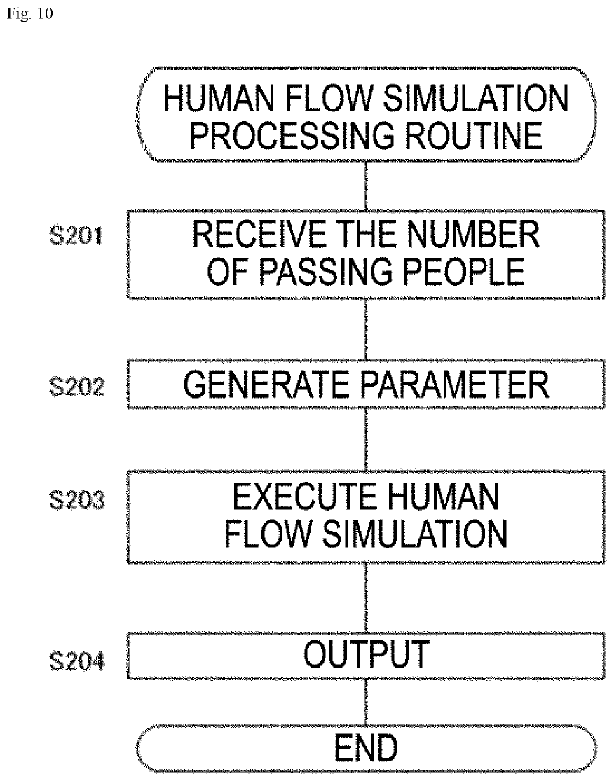

Next, effects of the server 20 will be described. FIG. 10 is a flowchart illustrating a sequence of a human flow simulation processing routine by the server 20. The CPU 21 reads a human flow simulation program from the ROM 22 or the storage 24, loads the human flow simulation program into the RAM 23, and executes the human flow simulation program, whereby the human flow simulation processing routine is performed.

In step S201, the CPU 21 serves as the reception unit 201, and receives, from the human flow measurement apparatus 10, the number of passing people through each of a plurality of points.

In step S202, the CPU 21 serves as the parameter generation unit 202, and generates a parameter for executing a human flow simulation, based on the number of passing people through each of the plurality of points being received in step S201 described above, and predetermined simulation information.

In step S203, the CPU 21 serves as the simulation execution unit 203, and executes the human flow simulation, based on the parameter generated in step S202 described above, and the predetermined simulation information.

In step S204, the CPU 21 serves as the output unit 204, and outputs a simulation result executed in step S203 described above.

As described above, the human flow measurement apparatus 10 according to the embodiment of the present disclosure receives an input of passage information indicating passage through a point, measures the number of passing people through the point by adding the received passage information, and transmits the number of passing people measured at a predetermined time interval to a server that generates a parameter of a human flow simulation. Thus, the human flow simulation can be performed in real time.

Further, the human flow simulation system 1 according to the embodiment of the present disclosure receives an input of passage information indicating passage through a point, measures the number of passing people through the point by adding the received passage information, and generates a parameter for executing a human flow simulation, based on the number of passing people measured at a predetermined time interval and predetermined simulation information. Thus, the human flow simulation can be performed in real time.

### Outline of Human Flow Simulation System According to Second Embodiment

In the first embodiment, a parameter of a human flow simulation is generated by using the number of passing people being received from the human flow measurement apparatus, based on an operation by a measurer. In the present embodiment, a case where the number of passing people being measured by a sensor is also used will be described. Since the number of passing people is measured based on visual inspection by a measurer in a measurement by the human flow measurement apparatus, the measurement accuracy is high. Meanwhile, a cost of employment of a measurer is high, and a continuous measurement is difficult. On the other hand, once the sensor is installed, the cost is lower than that in the case of a measurer. However, a measurement of the number of passing people by the sensor decreases in accuracy in the nighttime, rain, a period of congestion, and the like.

In the present embodiment, the number of passing people measured by the sensor is calibrated by the number of passing people measured by the human flow measurement apparatus. A result acquired when calibration is performed is accumulated. After a predetermined period of time has elapsed since the measurement starts, a parameter of a human flow simulation is generated by using the result of performing the calibration and the number of passing people measured by the sensor.

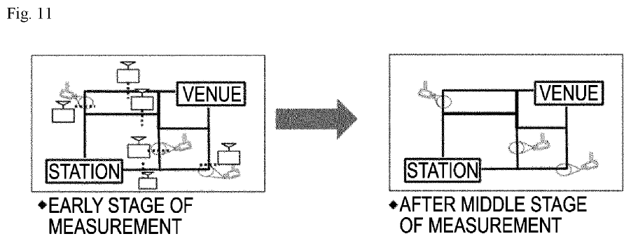

In other words, as illustrated in FIG. 11, in an early stage of a measurement, a visual measurement by a measurer is performed simultaneously with a measurement by the sensor, and thus calibration is performed on the number of passing people measured by the sensor with, as correct data, the number of passing people measured by the measurer. After a predetermined period of time has elapsed, i.e., after a middle stage of the measurement, only the number of passing people measured by the sensor is used based on a result of performing the calibration.

With such a configuration, it is possible to increase the measurement accuracy of the number of passing people by the sensor, and to perform a human flow simulation in real time at low cost.

Configuration of Human Flow Simulation System According to Second Embodiment Hereinafter, an example of a second embodiment of the disclosed technique will be described with reference to the drawings. In the drawings, the same reference numerals are given to the same or equivalent constituent elements and parts. The dimensional ratios in the drawings are exaggerated for convenience of explanation and may differ from the actual ratios.

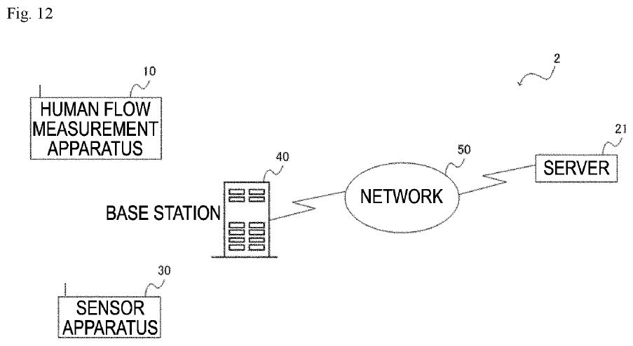

FIG. 12 is a diagram illustrating a configuration of a human flow simulation system 2 according to the present embodiment. As illustrated in FIG. 12, the human flow simulation system 2 includes a human flow measurement apparatus 10, a server 25, a plurality of sensor apparatuses 30, a base station 40, and a network 50. The human flow measurement apparatus 10, the server 25, and the plurality of sensor apparatuses 30 communicate with each other via the base station 40 and the network 50.

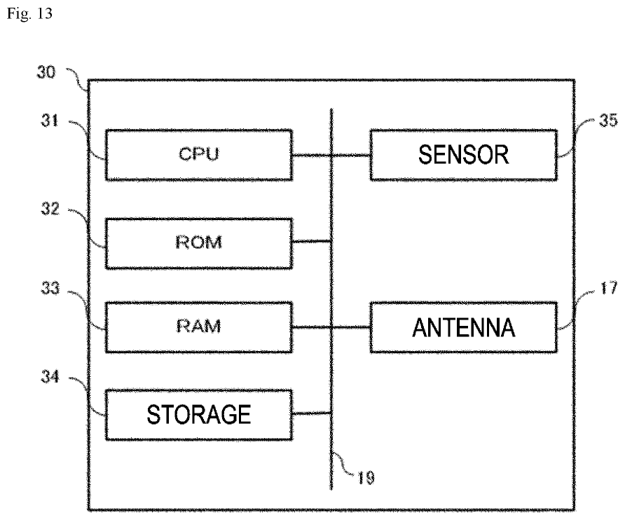

FIG. 13 is a block diagram illustrating a hardware configuration of the sensor apparatus 30 according to the present embodiment. As illustrated in FIG. 13, the sensor apparatus 30 includes a CPU 31, a ROM 32, a RAM 33, a storage 34, a sensor 35, and an antenna 17. The components are communicably interconnected through a bus 19.

The CPU 31 is a central processing unit that executes various programs and controls each unit. In other words, the CPU 31 reads a program from the ROM 32 or the storage 34 and executes the program using the RAM 33 as a work area. The CPU 31 performs control of each of the components described above and various arithmetic processing operations in accordance with a program stored in the ROM 32 or the storage 34. In the present embodiment, a sensor measurement program is stored in the ROM 32 or the storage 34.

The ROM 32 stores various programs and various kinds of data. The RAM 33 is a work area that temporarily stores a program or data. The storage 34 is constituted by an HDD or a SSD, and stores various programs including an operating system and various kinds of data.

The sensor 35 is a sensor for detecting the number of passing people through a point at which the human flow measurement apparatus 10 measures the number of passing people. The sensor 35 detects the number of passing people by using a camera, a laser, or the like. For example, the number of passing people through the same point as the human flow measurement apparatus 10, which can be observed from a place where the sensor 35 is installed, is measured.

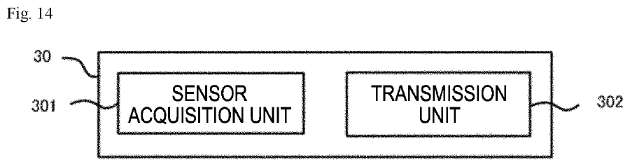

Next, a functional configuration of the sensor apparatus 30 will be described. Note that a point is set in advance. FIG. 14 is a block diagram illustrating an example of the functional configuration of the sensor apparatus 30. As illustrated in FIG. 14, the sensor apparatus 30 includes, as a functional configuration, a sensor acquisition unit 301 and a transmission unit 302. Each of the functional configurations is implemented by the CPU 31 reading a sensor measurement program stored in the ROM 32 or the storage 34, and loading the sensor measurement program in the RAM 33 to execute the program.

The sensor acquisition unit 301 acquires, from the sensor 35, the number of passing people through a point at which the human flow measurement apparatus 10 measures the number of passing people. Then, the sensor acquisition unit 301 passes the acquired number of passing people to the transmission unit 302.

The transmission unit 302 transmits, to the server 25, the number of passing people acquired by the sensor acquisition unit 301 at a predetermined time interval.

A hardware configuration of the server 25 according to the present embodiment is similar to that of the server 20 according to the first embodiment, and the description thereof will thus be omitted.

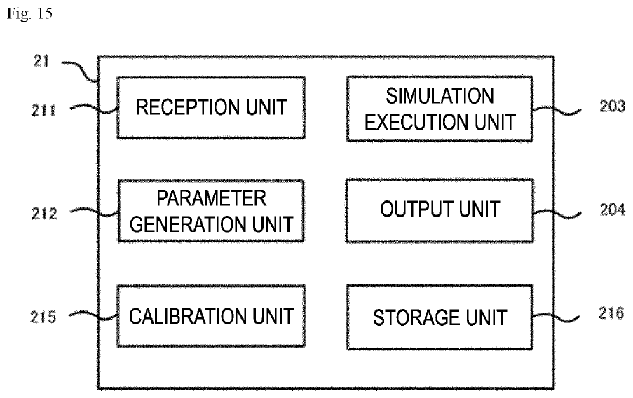

Next, a functional configuration of the server 25 will be described. FIG. 15 is a block diagram illustrating an example of the functional configuration of the server 25. As illustrated in FIG. 15, the server 25 includes, as a functional configuration, a reception unit 211, a parameter generation unit 212, a simulation execution unit 203, an output unit 204, a calibration unit 215, and a storage unit 216.

The reception unit 211 has a function similar to that of the reception unit 201. The reception unit 211 further receives the number of passing people from the sensor apparatus 30. Then, the reception unit 211 passes, to the calibration unit 215, the number of passing people received from the sensor apparatus 30.

The reception unit 211 receives the number of passing people only from the sensor apparatus 30 after a predetermined period of time has elapsed from a measurement start time. Note that the measurement start time may be acquired by, for example, receiving, from the human flow measurement apparatus 10, a time at which the “start (restart)/pause” button on the screen displayed by the display unit 101 is tapped.

The calibration unit 215 performs calibration on the number of passing people received from the sensor apparatus 30 with, as correct data, the number of passing people received from the human flow measurement apparatus 10. In the present embodiment, description is given with, as a result of performing calibration, a difference between the number of passing people received from the sensor apparatus 30 and the number of passing people received from the human flow measurement apparatus 10. Note that another calibration method may be used. For example, by associating sensor data (for example, image data) measured by the sensor 35 with the number of passing people being correct data, and learning a model for deriving the number of passing people from the sensor data, a parameter of the model may be calibrated. Then, the calibration unit 215 stores the result of performing the calibration in the storage unit 216.

The storage unit 216 stores the result of the calibration performed by the calibration unit 215.

The parameter generation unit 212 has a function similar to that of the parameter generation unit 202. The parameter generation unit 212 generates a parameter, based on the result stored in the storage unit 216, the number of passing people received from the sensor apparatus 30, and simulation information, after a predetermined period of time has elapsed since a measurement starts. Specifically, the parameter generation unit 212 first acquires the result of performing the calibration stored in the storage unit 216. Next, the parameter generation unit 212 determines an average of the results of performing the calibration. The parameter generation unit 212 generates a parameter, based on the determined average of the results, the number of passing people received from the sensor apparatus 30, and simulation information. In other words, the parameter generation unit 212 corrects the number of passing people received from the sensor apparatus 30 with the determined average of the results as a calibration amount, and generates a parameter. Then, the parameter generation unit 212 passes the generated parameter to the simulation execution unit 203.

### Effect of Human Flow Simulation System According to Second Embodiment

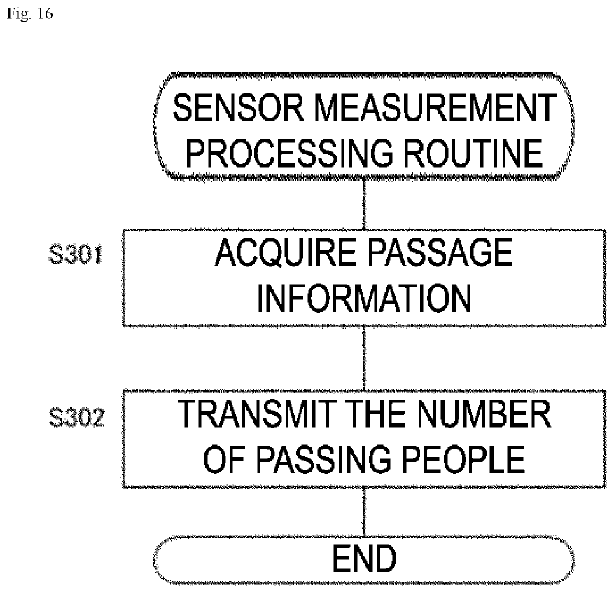

Next, effects of the sensor apparatus 30 will be described. FIG. 16 is a flowchart illustrating a sequence of a sensor measurement processing routine by the sensor apparatus 30. The CPU 31 reads a sensor measurement program from the ROM 32 or the storage 34, loads the sensor measurement program into the RAM 33, and executes the sensor measurement program, whereby the processing by the sensor apparatus 30 is performed.

In step S301, the CPU 31 serves as the sensor acquisition unit 301, and acquires, from the sensor 35, the number of passing people through a point at which the human flow measurement apparatus 10 measures the number of passing people.

In step S302, the CPU 31 serves as the transmission unit 302, and transmits, to the server 25, the number of passing people acquired by the sensor acquisition unit 301 at a predetermined time interval.

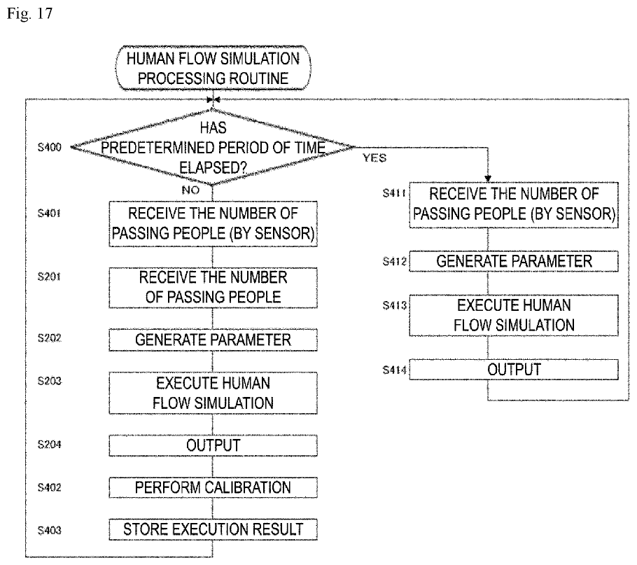

Next, effects of the server 25 will be described. FIG. 17 is a flowchart illustrating a sequence of a human flow simulation processing routine by the server 25. The CPU 21 reads a human flow simulation program from the ROM 22 or the storage 24, loads the human flow simulation program into the RAM 23, and executes the human flow simulation program, whereby the human flow simulation processing routine is performed. Note that processing similar to that of the server 20 will be given the same reference signs, and descriptions thereof will be omitted.

In step S400, the CPU 21 serves as the reception unit 211, and determines whether a predetermined period of time has elapsed since a measurement starts.

In accordance with a determination that the predetermined time interval has not elapsed (NO in step S400 described above), the CPU 21 serves as the reception unit 211, and receives the number of passing people from the sensor apparatus 30 in step S401.

In step S402, the CPU 21 serves as the calibration unit 215, and performs calibration on the number of passing people received in step S401 described above with, as correct data, the number of passing people received in step S201 described above.

In step S403, the CPU 21 serves as the calibration unit 215, and stores a result of performing the calibration in step S402 described above in the storage unit 216, and the processing returns to step S400.

On the other hand, in accordance with a determination that the predetermined time interval has elapsed (YES in step S400 described above), the CPU 21 serves as the reception unit 211, and receives the number of passing people from the sensor apparatus 30 in step S411.

In step S412, the CPU 21 serves as the parameter generation unit 212, and generates a parameter, based on the result of performing the calibration acquired in step S411 described above, the number of passing people received from the sensor apparatus 30, and simulation information.

In step S413, the CPU 21 serves as the simulation execution unit 203, and executes a human flow simulation, based on the parameter generated in step S412 described above, and the predetermined simulation information.

In step S414, the CPU 21 serves as the output unit 204, and outputs a simulation result executed in step S413 described above, and the processing returns to step S410.

As described above, the human flow simulation system 2 according to the embodiment of the present disclosure further includes a sensor apparatus, where the sensor apparatus includes acquiring the number of passing people from a sensor for detecting the number of passing people through a point at which the human flow measurement apparatus measures the number of passing people, and transmitting, to the server, the number of passing people acquired at a predetermined time interval, the reception unit further receives the number of passing people from the sensor apparatus, the server performs calibration on the number of passing people received from the sensor apparatus with, as correct data, the number of passing people received from the human flow measurement apparatus, and stores a result of performing the calibration, and, after a predetermined period of time has elapsed since a measurement start time, the server receives the number of passing people only from the sensor apparatus, and generates the parameter, based on the stored result, the number of passing people received from the sensor apparatus, and the simulation information. Thus, it is possible to increase the measurement accuracy of the number of passing people by the sensor, and to perform a human flow simulation in real time at low cost.

The present disclosure is not limited to the above embodiments and various modifications and applications are possible without departing from the gist of the present invention.

For example, in the embodiments described above, the human flow measurement apparatus and the server are described as separate apparatuses, but may be configured as one apparatus. Further, the human flow measurement apparatus, the server, and the sensor apparatus are described as separate apparatuses, but all of the apparatuses may be configured as one apparatus, or any two apparatuses may be configured as one apparatus.

In the embodiments described above, a configuration in which one sensor apparatus 30 performs a measurement at one point has been described as an example, but the present invention is not limited thereto, and one sensor apparatus 30 may be configured to perform a measurement at a plurality of points.

Further, in the embodiments described above, the number of passing people through the same point may be configured to be measured for each of a plurality of directions. For example, the number of passing people in a direction of Tokyo and the number of passing people in a direction of Yokohama can be configured to be measured at a certain point. In this case, names of a point and a direction and a counter being a current number of measurements are displayed on the “count-up button”. Further, a point at which a measurement is performed regardless of a direction of passage and a point at which a measurement is performed in consideration of a direction of passage may be configured to be combined.

Further, in the embodiments described above, a case where the number of passing people measured by the human flow measurement apparatus is transmitted to the server at a time interval suitable for executing a real-time simulation is described, but the present invention is not limited thereto. For example, as illustrated in FIG. 5, the number of passing people may be transmitted to the server every time the number of passing people is counted at a predetermined time width (for example, one second). In other words, in the example in FIG. 5, the number of passing people in each row (each record) is transmitted to the server every second. Then, information about the received number of passing people may be accumulated in the server, and the number of passing people at a predetermined time interval (for example, one minute) may be counted to execute a simulation.

Note that, in the embodiments described above, various processors other than the CPU may execute each processing which the CPU executes by reading software (program). Examples of the processor in such a case include a programmable logic device (PLD) such as a field-programmable gate array (FPGA) the circuit configuration of which can be changed after manufacturing, a dedicated electric circuit such as an application specific integrated circuit (ASIC) that is a processor having a circuit configuration designed dedicatedly for executing the specific processing, and the like. Further, each program may be executed by one of these various processors or a combination of two or more processors of the same type or different types (for example, a combination of a plurality of FPGAs and a combination of a CPU and an FPGA). More specifically, the hardware structure of such various processors is an electrical circuit obtained by combining circuit devices such as semiconductor devices.

In each of the embodiments described above, although a form in which the each program is stored (installed) in the ROM or the storage in advance has been described, the form is not limited thereto. Each program may be provided in the form of being stored in a non-transitory storage medium such as a compact disk read only memory (CD-ROM), a digital versatile disk read only memory (DVD-RAM), or a universal serial bus (USB) memory. Each program may be in a form that is downloaded from an external apparatus via a network.

With respect to the embodiments described above, the following supplementary notes are further disclosed.

### Supplementary Note 1

A human flow measurement apparatus, including:
a memory; and
at least one processor connected to the memory, wherein
the processor
receives an input of passage information indicating passage through a point,
measures the number of passing people through the point by adding the passage information received at the input unit, and
transmits the number of passing people measured at the measurement unit at a predetermined time interval to a server that generates a parameter of a human flow simulation.

### Supplementary Note 2

A non-transitory storage medium that stores a human flow measurement program causing a computer to execute:
receiving an input of passage information indicating passage through a point;
measuring the number of passing people through the point by adding the passage information received at the input unit; and
transmitting the number of passing people measured at the measurement unit at a predetermined time interval to a server that generates a parameter of a human flow simulation.

### REFERENCE SIGNS LIST

1, 2 Human flow simulation system
10 Human flow measurement apparatus
11, 21, 31 CPU
12, 22, 32 ROM
13, 23, 33 RAM
14, 24, 34 Storage
15 Input unit
16 Display unit
17 Antenna
19 Bus
20, 25 Server
24 Storage
27 Communication interface
30 Sensor apparatus
35 Sensor
40 Base station
50 Network
101 Display unit
102 Input unit
103 Measurement unit
104 Transmission unit
201, 211 Reception unit
202, 212 Parameter generation unit
203 Simulation execution unit
204 Output unit
215 Calibration unit
216 Storage unit
301 Sensor acquisition unit
302 Transmission unit

1. A human flow measurement apparatus comprising a circuit configured to execute a method comprising:
receiving an input of passage information indicating passage through a point among a plurality of points;
measuring a number of passing people through the point by adding the passage information; and
transmitting the number of passing people at a predetermined time interval to a server that generates a parameter of a human flow simulation.

2. The human flow measurement apparatus according to claim 1, the circuit further configured to execute a method comprising:
displaying the passage information about one or more points of the plurality of points, wherein
the receiving further receives an input of the passage information about the one or more points of the plurality of points,
the measuring further measures the number of passing people through the point by adding the passage information about the one or more points of the plurality of points, and
the transmitting further transmits, to the server, the number of passing people through the one or more points of the plurality of points at the predetermined time interval.

3. A human flow simulation system comprising a circuit configured to execute a method comprising:
receiving an input of passage information indicating passage through a point among a plurality of points;
measuring a number of passing people through the point by adding the passage information;
transmitting the number of passing people at a predetermined time interval to a server that generates a parameter of a human flow simulation; and
generating a parameter for executing a human flow simulation, based on the number of passing people and predetermined simulation information.

4. The human flow simulation system according to claim 3, the circuit further configured to execute a method comprising
acquiring, by a sensor, the number of passing people from a sensor for detecting the number of passing people through the point;
transmitting, by a sensor, the number of passing people at the predetermined time interval;
calibrating on the number of passing people acquired by the sensor with, as correct data, the number of passing people measured;
storing a result of the calibrating:
after a predetermined period of time has elapsed since a measurement start time;
receiving the number of passing people only from the sensor; and
generating the parameter, based on a combination including the result, the number of passing people received from the sensor, and the predetermined simulation information.

5. (canceled)

6. A computer-implemented method for simulating human flow, the method comprising:
receiving an input of passage information indicating passage through a point among a plurality of points;
measuring the number of passing people through the point by adding the passage information received at the input unit;
transmitting the number of passing people measured at the measurement unit at a predetermined time interval;
receiving the number of passing people; and
generating a parameter for executing a human flow simulation, based on the received number of passing people and predetermined simulation information.

7-8. (canceled)

9. The human flow measurement apparatus according to claim 1, wherein the transmitting the number of passing people at the predetermined time interval causes a real time simulation of human flow.

10. The flow simulation system according to claim 3, wherein the transmitting the number of passing people at the predetermined time interval causes a real time simulation of human flow.

11. The human flow simulation system according to claim 3, the circuit further configured to execute a method comprising:
displaying the passage information about one or more points of the plurality of points at the predetermined time interval.

12. The computer-implemented method according to claim 6, wherein the transmitting the number of passing people at the predetermined time interval causes a real time simulation of human flow.

13. The computer-implemented method according to claim 6, the method further comprising:
displaying the passage information about one or more points of the plurality of points at the predetermined time interval.
